(19) United States
(12) Patent Application Publication
(10) Pub. No.: US 2011/0100406 A1
(43) Pub. Date: May 5, 2011

(54) SPLIT THERMO-ELECTRIC STRUCTURE AND DEVICES AND SYSTEMS THAT UTILIZE SAID STRUCTURE

(75) Inventor: Noam Danenberg, Hod Hasharon (IL)

(73) Assignee: LAMOS INC., Beersel (BE)

(21) Appl. No.: 13/001,321

(22) PCT Filed: Jul. 2, 2009
(86) PCT No.: PCT/IL09/00666

§ 371 Date: Dec. 23, 2010

(30) Foreign Application Priority Data
Jul. 6, 2008 (IL) 192647
Sep. 8, 2008 (IL) 193972

(51) Int. Cl. H01L 35/28; H01L 35/32

(52) U.S. Cl. 136/203; 136/205; 136/206; 136/212

(57) ABSTRACT

The invention is a Split-Thermo-Electric Structure (STES) and devices and systems that utilize said structure. The STES comprises a first thermo-electric element at an elevated temperature and a second thermo-electric element at a low (cold) temperature. The first thermo-electric element and the second thermo-electric element are connected by either an intermediate connection that conducts both electric current and heat or by a thermo-electric chain comprised of one or more thermo-electric elements. Each pair of the thermo-electric elements in the chain are connected by an intermediate connection that conducts both electric current and heat. Each of the thermo-electric elements and each of the intermediate connections in the STES exhibit a temperature-gradient. The STESs can be utilized in Seebeck or Peltier devices. The STESs can be utilized to construct devices comprised a plurality of n-type and p-type pairs of STESs, wherein each of the STESs in the device are connected at each end to a support layer. One of the support layers can be thermally connected to a heat source and the second support layer thermally connected to a heat sink in order to create a thermo-electric system. The heat source or the heat sink or both can be located at a distance from their respective support layer.

### FIELD OF THE INVENTION

The present invention relates to a novel thermo-electric technology, based on split thermo-electric structure.

### BACKGROUND OF THE INVENTION

Thermo-electric systems for cooling or for power generation are of high interest in a wide range of processes and applications. The structure of existing conventional thermo-electric modules puts unavoidable limitations on the magnitude of the heat flux that can be transferred between the heat absorbing and heat dissipating sides of the module.

The physical principles on which thermo-electric effects are based, i.e. the Seebeck Effect and the Peltier Effect, are well-known since 1821 and 1834, respectively. The Seebeck Effect relates to an electric current which will flow continuously in a closed circuit composed of two dissimilar metals or conductors as long as the connections between the two materials are maintained at a given temperature gradient. Conversely, the Peltier Effect states that when an electrical current flows through a circuit composed of different metals or conductors a heat flow, and hence a temperature gradient, will take place across the connection of the two metals or conductors.

Although these phenomena were comprehensively explained by William Thomson (Lord Kelvin) in the 1850's they remained essentially without practical application until the middle of the twentieth century.

Any metal exhibits both the Seebeck Effect and/or the Peltier Effect both of which depend on the electrical conductivity, ke, and the thermal conductivity, kt, of the metal. However, a significant thermoelectric effect is measured only when the Seebeck coefficient and the electrical conductivity are large while the thermal conductivity is small. This is well-indicated by the so-called “Figure of the Merit”, Z, of a material over a range of temperature, whereby:

Z=α²ke/kt equation (1)

where—
α is the thermo-electric Seebeck coefficient
kₜ is the thermal conductivity
ke is the electrical conductivity

However, for metals the electrical conductivity goes together with thermal conductivity, i.e. good electrical conductors are also good thermal conductors. This may be the main reason that the application of thermo-electric effects to practical technological systems has been held back until recent times.

The use of thermo-electric semi-conductor materials in the last decades has formed the basis for an enormous volume of applications in high technology areas; to name a few these are electronics, space, medical, energy transport and other scientific operations.

The basic thermo-electric technology is in fact represented by thermo-electric modules which include varying amounts (typically hundreds) of thermo-couples, whereby each unit of thermo-couple consists in principle of a p-type and n-type semi-conductor elements. In general, these elements are electrically connected in series, and are thermally connected in parallel. FIG. 1 symbolically shows a portion of a typical prior art thermo-electric module 10 sandwiched between an intermediate substrate 12′ in thermal contact with heat source 12 and intermediate substrate 14′ in thermal contact with heat sink 14. Module 10 is comprised of pairs of P type and N type semiconductor elements 16_{P} and 16_{N} electrically connected in series, by means of metallic conductor tabs 18. The external electric connections to the positive and negative poles of a DC power source are symbolically shown by connections 22 and 24 respectively. The semiconductor elements are thermally connected in parallel. To stabilize the structure, the tops and bottoms of the semi-conductor elements 16_{P} and 16_{N} are pressed between ceramic plates 20. In the figure the arrows indicate the direction of heat flow.

It is worth noting that the height of a typical module ranges between 2-4 mm. The significance of this fact will become apparent as the description proceeds, since it relates not only to the close vicinity between the heat absorption and heat dissipation mechanisms at both sides of the thermo-electric module, but also to other critical operational parameters.

Clearly, it can be seen from FIG. 1 that the geometry of the thermo-electric structure, the physical properties of the materials, and the electrical and thermal resistances are the factors that, taken all together, determine the overall performance of the thermo-electric module.

The relations of these parameters to the module power are well-known in the literature and can be expressed as:

$$P = \frac{{α}^{2} {{NA}^{*} ( {T}_{h} - Tc )}^{2}}{2 r ( L + r / {r}_{c} ) {( 1 + 2 ( λ / {λ}_{c} ) ( Lc / L ) )}^{2}} \qquad equation ( 2 )$$

### Where:

P is the module power
N is the number of elements
Tₕ is the module hot side temperature
L is the element length
r is the electrical resistivity (1/ke)
λ is the thermal resistivity of the module (1/kt)
α is the Seebeck coefficient
A is the area of elements
T_{c} is the module cold side temperature
L_{c} is the thickness of the insulating ceramic
r_{c} is the contact electrical resistivity
λ_{c} is the contact thermal resistivity

The disadvantages of the prior art thermo-electric modules can be deduced from consideration of FIG. 1 and equation (2). The most critical disadvantages and limitations are:

(a) The basic function of the thermo-electric module is to pull heat from the cold sink and push it into the heat sink, in the case of thermo-electric coolers or refrigerators; or vice versa, in the case of thermo-electric heaters. Thus, any high performance thermo-electric module requires a very effective heat sink to dissipate both the thermal heat from the high temperature face, and the heat developed by the electrical current and/or cold sink to absorb the heat. To accomplish this task complicated large finned heat exchangers are almost always necessary. However, there are various mechanical constraints which complicate or totally prevent successful thermal coupling of the thermo-electric module to the cold and heat sinks. The first of these constraints is the shape of the standard module, which means that it can only be coupled to heat sinks having a very specific geometry. The second constraint is the coupling between the heat transfer mechanisms at the cold and hot face caused by the close vicinity of the two faces. Since the “hot” and “cold faces of the standard thermo-electric modules are in fact very close to each other, thermo-electric systems always require a special design and extra components to ensure an optimal rate of heat transport on one or both of the hot and cold sides.
(b) Considering equation (2) and ignoring the interfacial resistances at the various contact faces the expression for the power can be simplified to:

$$P = \frac{{α}^{2} {NA ( Δ T )}^{2}}{2 rL} \qquad equation ( 3 )$$

Thus, the power may be increased by decreasing the length L of the semiconductor elements. However, this makes the difficulties described above (in paragraph (a) more and more difficult to overcome.

Furthermore, by reducing the separation distance between the hot and cold junctions the effect of thermal diffusion due to the increased temperature gradient (ΔT/ΔL) is significantly enhanced, whereby the performance of the overall thermo-electric module deteriorates.

(c) Equation (3) is true for an “ideal module”, for which the thermal contact resistances are neglected. However, both the external interfacial thermal resistances between the module and the heat sink or the heat source, as well as the intrinsic interfacial resistances between the P,N pellets and the ceramic layers, play a significant role. It is of high importance to keep all interfacial resistances to the minimum values possible. Improper metallization of the ceramics, for instance, or improper soldering or improper nickel-plating are only a few of the potential problems which put in question the survivability and reliability of the thermo-electric module. To avoid unnecessary interfacial resistances, the surfaces are required to be very flat (within 0.001″) and uniform clamping pressure (up to 200 psi) must be applied. The mounting surfaces on the heat source and sink between which modules are to be clamped as well as the module ceramic surfaces should be flat within 0.001″ and carefully fabricated without any grit, burrs, etc. In fact, the biggest challenge facing the manufacturer of an optimal thermo-electric module is to maintain an essentially even flatness and compression across all the module elements.
(d) In utilizing thermo-electric modules for power generation systems, the temperature difference should be maintained constant by strict localized thermal management. Clearly, the presently available standard thermo-electric modules make it impossible to use available by-product waste heat because the parameters, e.g. dimensions, shape, and location, of the heat source are not compatible with the structure of the thermo-electric modules. For example, the close vicinity between the “hot” and “cold” faces may not allow the use of available sources of heat or the use of cold zones such as: waste heat or rejected heat, exhaust gas in pipes or from vehicles, heat lost from hot engines, utilization of solar energy, heat dissipation from moving bodies, etc.

In view of the general descriptions above of the limitations and obstacles which are inherent to the standard thermo-electric modules, the goal of the present invention is to remove the above critical limitations by providing a novel structure of thermo-electric modules, which allows a new approach to the design of thermo-electric systems as well as to the implementation of new, large-scale thermo-electric systems and processes.

Further purposes and advantages of this invention will appear as the description proceeds.

### SUMMARY OF THE INVENTION

In a first aspect the invention is a Split-Thermo-Electric Structure (STES) comprising a first thermo-electric element and a second thermo-electric element. The first and second thermoelectric elements are located at a distance from one another; the first thermo-electric element is at an elevated temperature and the second thermo-electric element is at a low (cold) temperature; and the first thermo-electric element and the second thermo-electric element are connected by either an intermediate connection that conducts both electric current and heat or by a thermo-electric chain comprised of one or more thermo-electric elements. Each pair of the thermo-electric elements in the chain are connected by an intermediate connection that conducts both electric current and heat. Each of the thermo-electric elements and each of the intermediate connections between two thermo-electric elements in the chain exhibits a temperature-gradient.

The thermo-electric elements are each made of one of the following types of material: a metal, a p-type semi-conductor material, an n-type semi-conductor material or an i-type semi-conductor material. At least some of the thermo-electric elements in the STES can be made of different materials and/or can have different dimensions.

The STES can be a Seebeck device, in which case the connections between the first and the second elements are maintained at different temperatures such at to generate an electrical current along the connections that connect them.

The STES can be a Peltier device, in which case a current is caused to flow through the connections that connect the first and the second elements, thereby to cool the first element and heat the second element.

In a second aspect the invention is a system utilizing one or more STESs that are Seebeck devices. The source of heat is from waste heat, e.g. waste heat generated by a vehicle. The source of heat can be the sun. In embodiments of this aspect of the invention the second element is cooled by the cooling system of a moving vehicle.

In a third aspect the invention is a thermo-electric device comprising a plurality of pairs of STESs according to the first aspect of the invention. In devices according to this aspect one STES in each pair is comprised of p-type semiconductor elements and the other STES in the pair is comprised of n-type semiconductor elements. The first thermo-electric element of each STES in the device is attached to a first support layer and the second thermo-electric element of each STES in the device is attached to a second support layer. The first and the second support layers comprise metallic conductor tabs on their surface that electrically connect all STESs in the device in series.

In a fourth aspect the invention is a system utilizing the thermo-electric device of the third aspect, wherein the first support layer is thermally connected to a heat source and the second support layer is thermally connected to a heat sink. The system of this aspect can be a Seebeck device, wherein the first support layer and the second support layer are maintained at different temperatures such at to generate an electrical current along the STESs that connect them. The system of this aspect can be a Peltier device, wherein a current is caused to flow through the STESs that connect the first support layer and the second support layer, thereby to cool the first support layer and heat the second support layer. In embodiments of this aspect of the invention either the heat source or the heat sink or both are located at a distance from their respective support layer.

### BRIEF DESCRIPTION OF THE DRAWINGS

In the drawings:

FIG. 1 schematically illustrates a thermo-electric module according to the prior art;

FIG. 2 schematically illustrates the characterizing features of the thermo-electric device of the invention;

FIG. 3 schematically shows an embodiment of the thermo-electric device of the invention comprised of thermo-electric pellets having different dimensions;

FIGS. 4A to 4C schematically show embodiments of the thermo-electric device of the invention comprised of multiple stages; and

FIGS. 5A, 5B, 6A, 6B, 6C, and 7 are graphs showing the temperatures at the interfaces between elements of different examples of the thermo-electric structures shown in FIGS. 4A to 4C.

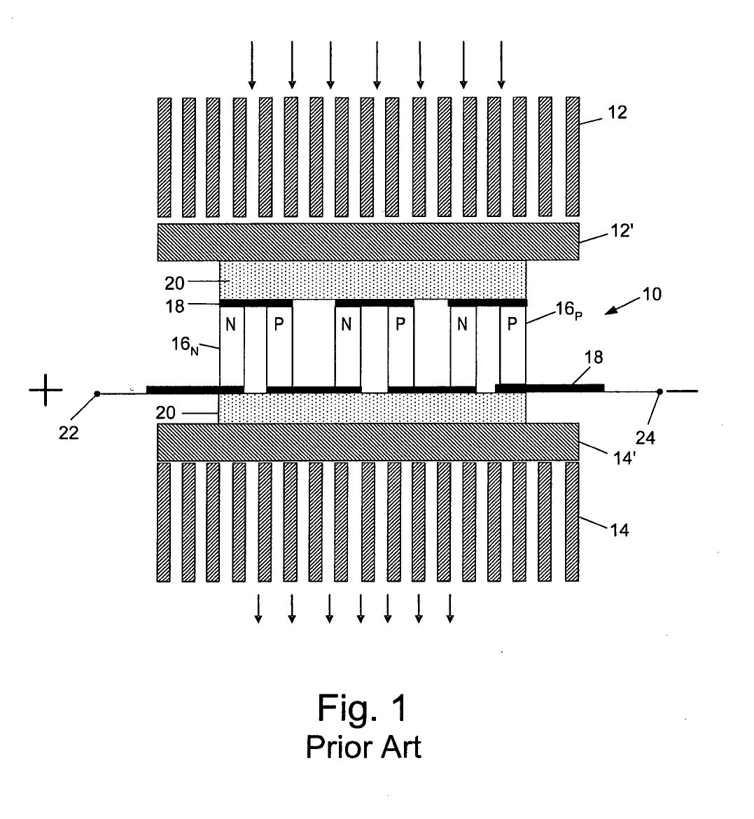

### DETAILED DESCRIPTION OF THE INVENTION

Most advances in the field of thermo-electric technology have been made by increasing the conversion efficiency of thermo-electric materials, or by developing advanced thermo-electric components and systems, such as high efficiency integrated exchange technology, low electrical resistances for high power miniaturized devices, scale-up materials processing and component fabrication, etc. However, the developments in these areas may not necessary eliminate or reduce the critical obstacles which are inherent to the standard structure of the existing thermo-electric modules as described herein above.

The direction taken by the inventor in the present invention is to make changes in the basic structure of the standard thermo-electric modules. The invention is a thermo-electric structure, which is characterized by features that address most of the disadvantages and limitations of the existing standard thermo-electric modules. As will be described in detail herein below, the concept of the invention is to enable overall optimization of the thermo-electric device for a specific application by allowing the parameters of all components of the device to be individually adjusted to give the best results. For example, the invention will remove the requirement that surfaces of the thermo-electric elements are required to be very flat and that any clamping pressure must be applied. Removing these restrictions allows different approaches to increasing the efficiency of the thermo-electric devices to be tried. For example roughening the ends of the semiconductor pellets might increase the efficiency of heat transfer.

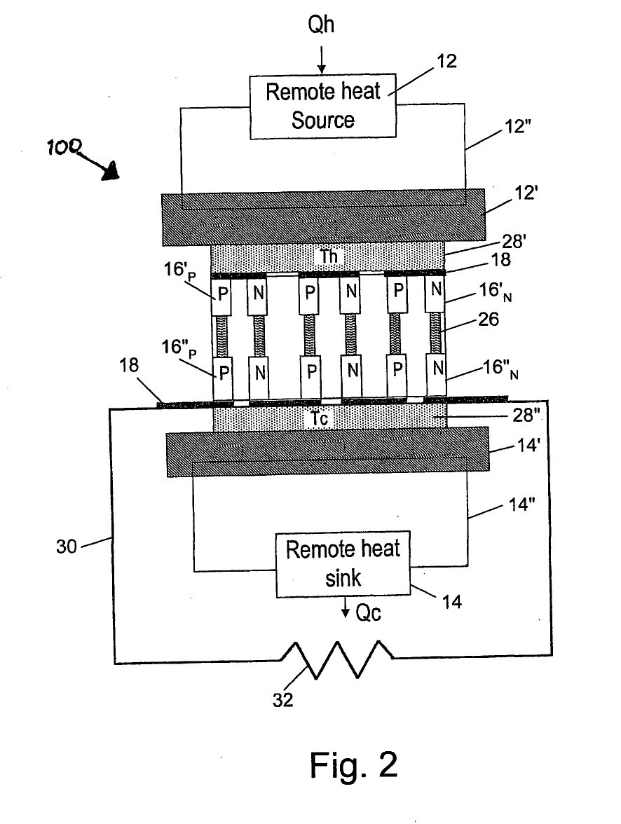

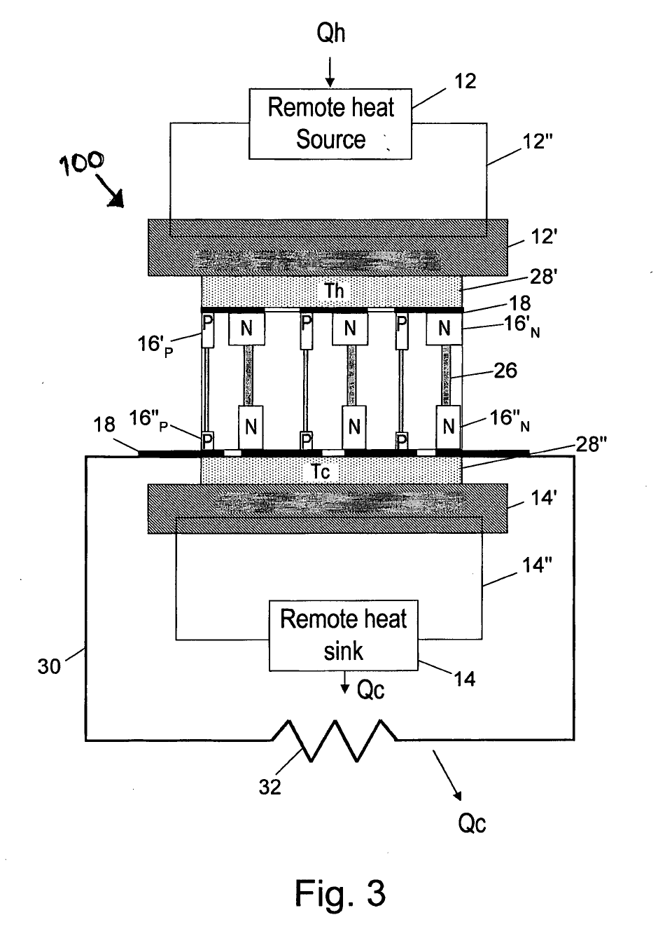

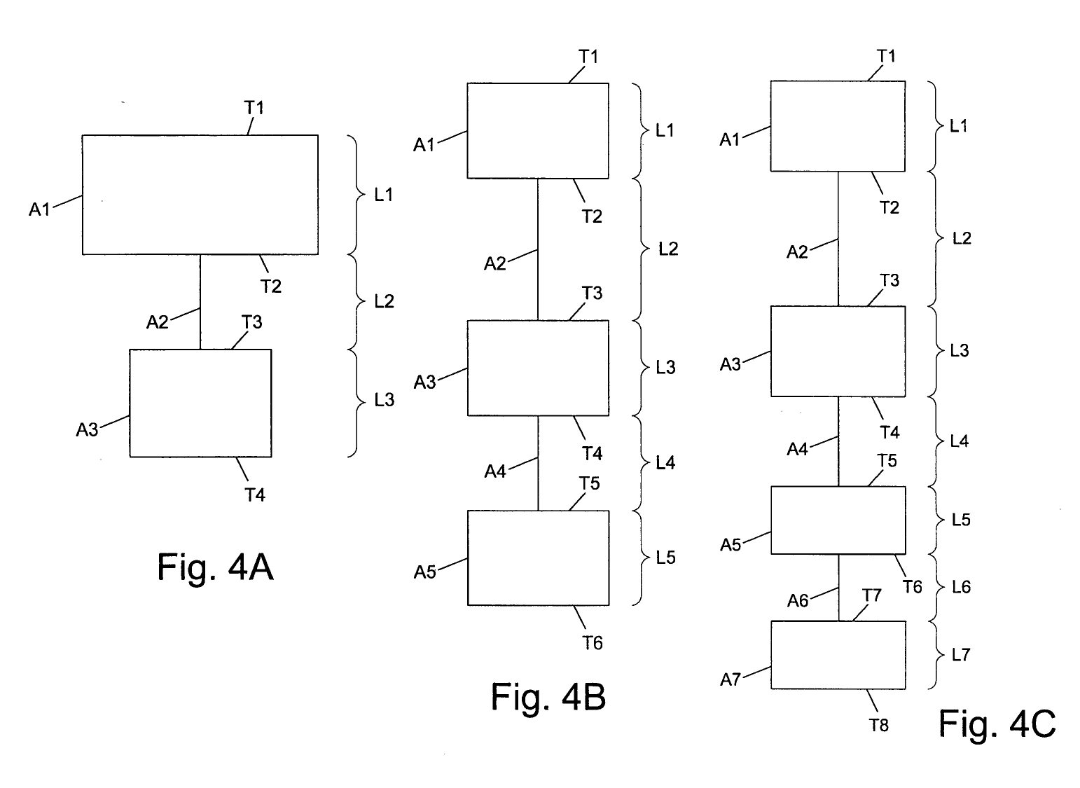

The principles of the invention will now be described for power generation with reference to FIG. 2. The mechanisms of the heat flow at the heat source and/or the heat sink are disengaged from the thermo-electric structure, as demonstrated in the figure. Also schematically shown is how the N-P pellets are divided into two dissimilar parts that are connected together by an intermediate connection (indicated by 26 in the figure). The invention is not to be understood as requiring that single thermo-electric elements have to be divided in two parts and then electrically and thermally rejoined by means of an appropriate intermediate connection. In practice two separate p-type or n-type pellets are used. Note that herein the terms “n-type” and “p-type” semiconductor elements refer to doped semiconductor material as in conventional usage and also to intrinsic, or i-type material. Furthermore, as will be discussed herein below with reference to FIG. 3, there is no requirement that the n-type and p-type pellets or the pellets on the hot and cold side be of the same type of material or dimensions. Additionally, as will be discussed herein below with reference to FIGS. 4A to 4C, the pellet of the conventional module can be “divided” into more than two parts resulting in multi-stage devices having a p,n-type pellet on the hot side, another p,n-type pellet on the cold side, and one or more p,n-type pellets in between with each pair of pellets in the chain connected by an intermediate connection.

The characterizing features of the thermo-electric device 100 of the invention are schematically illustrated in FIG. 2. For clarity, FIG. 2 shows the basic embodiment in which the p,n elements are each split into two pellets 16′_{P,N} and 16″_{P,N} that are electrically and thermally connected by intermediate connections 26. As in the prior art, pairs of pellets 16′_{P} and 16′_{N} and 16″_{P} and 16″_{N} are connected by metallic conductor tabs 18 that are attached to the support layers 28′, 28″, which are in thermal contact with intermediate substrates 12′ and 14′, which are in turn thermally coupled to heat source 12 and heat sink 14 by thermal coupling means 12″ and 14″ respectively. Support layers 28′, 28″ can be made of a large variety of materials subject to the condition that they possess the physical properties of non-electrical conductivity and resistance to high temperatures on the hot side and to low temperatures on the cold side. One example of a suitable support layer is a thin copper plate that is coated with a layer of non-electrical conducting material such as epoxy or a conventional PCB. In both cases a pattern of metallic conducting tabs 18 is created on the surface of the support layer to which the pellets are connected, e.g. by glue. In another embodiment the semiconductor pellets are “grown” onto the conducting pads using conventional techniques. As opposed to the prior art, according to the present invention heat source 12 and heat sink 14 do not have to be in actual physical contact with intermediate substrates 12′ and 14′. In the figure the external electrical circuit is symbolically shown as 30. For power generation circuit 30 comprises power generation means symbolically shown by resistor 32. For heating and cooling applications resistor 32 is replaced by a DC power source.

In order to keep the required figure of merit Z, the multiple intermediate connections 26 between the p,n pellets 16′_{P,N} located on the side of the remote heat source 12 and the p,n pellets 16″_{P,N} located on the side of the remote heat sink 14 are made of high electrical and thermal conductivity materials. As mentioned herein above, this requirement is easy to satisfy, since high electrical conductivity materials are also of high thermal conductivity. If indeed both electrical and thermal conductivities of the intermediate connections 26 are high (relative to the physical properties of the p,n pellets 16_{P,N}′,16_{P,N}″), then practically the intermediate connections 26 introduce almost electrical and thermal shorting between the pellets, whereas at both sides of the interconnection the p,n pellets still separate the electrical and thermal conductivities, Hence, the overall temperature gradient between the hot and cold junctions is maintained. Stated differently, the additional resistances of the intermediate connections 26 to the current or to the heat flow are of minor effect and therefore the performance of the thermo-electric p,n pellets can be controlled and optimized with all possible degrees of freedom such as height to area of each pellet at each stage and use of different materials. This will be explained in greater detail herein below.

Since the multiple connections to the remote heat source or the remote heat sink comprise thermal coupling means 12″ and 14″, which are made of high thermal conductivity materials or are comprised of any efficient heat transfer mechanism, e.g. liquid convection or an air radiator, the additional resistances of the external connections to the heat flow are of minor effect. However, since the heat sink, for instance, is not required to be in close vicinity of the hot face as in existing conventional thermo-electric modules, the dissipation of heat can be enhanced at an available remote “colder” heat sink, and thus the overall efficiency of the split unit may be optimized and even increased when compared to that of conventional modules.

As a result of the split structure of the invention, the heat source 12 and the heat sink 14 can be located apart from one another, without any limitation on the particular structure or orientation of either one. Instead of forcing an efficient heat source and an efficient heat sink to be tightly fitted to the close faces of standard thermo-electric modules, the invention allows the thermo-electric components to be adjusted to the location of heat sources and heat sinks that are available and may be located far apart from each other. Thus, according to the invention, thermo-electric systems can be designed according to the availability of existing heat sources or heat sinks. The split structure allows the design of any thermo-electric system, including most of the presently running applications, to become, in general, less complicated and more convenient with more degrees of freedom. Furthermore, the split-thermo-electric units of the invention allow large scale application challenges to be dealt with, as will be discussed herein below.

The split structure of the thermo-electric unit of the invention makes the mechanisms of the heat transfer at the heat source and the heat sink independent from each another and disengaged from the thermo-electric module. The remote heat source or remote heat sink can now each be treated separately with a high degree of freedom.

In view of equations (2) and (3), the output power and (thus the heat flux) can, in principle, be increased arbitrarily by decreasing the thermo-electric material height L and increased conditionally if the temperature gradient ΔT is successfully maintained constant and as large as possible. However in the existing standard thermo-electric modules as the height L of the p,n elements, decreases, it becomes dramatically more difficult to maintain the temperature gradient constant at a constant level. This difficulty is completely eliminated using the split structure of the invention.

Another feature of the split structure of the invention is the increased temperature gradient which can be achieved. Whereas in conventional thermo-electric modules the p,n elements are sandwiched closely between the high and low temperature zones, and therefore cannot be further reduced in height. Furthermore the requirement of extremely flat surfaces places a practical limit on the area A of the thermo-electric elements, which has a limiting effect on the module power (see equation (2)). In the split-thermo-electric structure, these limitations are eliminated, therefore it becomes possible to reduce the height of the thermo-electric material at both the side of the heat source and the heat sink to the minimum thickness needed as to maximize the temperature gradient, ΔT/ΔX, at each side. Also the cross-sectional area of the pellets can be increased. As a result, the practical height and cross-sectional areas of the p,n pellets is determined according to the specific physical system and is not limited by the thermo-electric module configuration only. It is of high importance to note that the split structure enables use of pellets having different dimensions (as shown symbolically in FIG. 3) and also pellets made of different thermo-electric material at the hot and cold sides. The latter is important since the properties and characteristics of the thermo-electric material are temperature-dependent and thus one can choose the material that will give the best results for the specific temperatures at the cold and hot zones in a particular application. In some applications the use of porous pellets or pellets with roughened ends will increase the effective contact area and therefore the thermal transfer will be increased. On the other hand, because of the presence of air in the pores, the thermal conductivity of the pellet will be reduced compared to that of a solid pellet.

The split structure with the features described herein above enables large scale systems to be designed and built. In view of equations (2) and (3), the power output is proportionate to both N, the number of the p,n elements and A, their cross-sectional area since the elements are in principle combined electrically in series. However, for prior art modules, it is impractical to increase either N or A because of the essential requirements of ensuring an even pressure across the module surfaces, uniform flatness, and because of other limitations related to thermal expansion/contraction issues, and stress created during heating or cooling.

FIG. 2 and FIG. 3 demonstrate the concept of the split thermo-electric structure, mainly with regard to the idea of allowing remote heat source and remote heat sink with non-continuous p,n pellets, interconnected by means of different intermediate connectors. These figures thus relate to the inner core of the thermo-electric module.

The split structure requires that the hot side p,n pellets and the cold side p,n pellets be connected by intermediate connector means 26 as schematically shown in FIG. 2. Clearly, it is required that the internal thermal and electrical resistances of the intermediate connectors be as small as possible. The additional resistances are compensated for by the reductions obtained from other features, e.g. thin p,n elements, larger cross-section A, higher temperature gradients, discussed herein above. Moreover, the intermediate connectors play a role in the dissipation of heat and thus positively contribute to structure performance. Referring to FIG. 2, thermo-electric effects will occur not only at the “external” junctions between the semiconductor material and the metallic conducting pads 18, as in the conventional thermo-electric module, but will also occur at the “internal” junctions between the semiconductor material and the intermediate connector 26. At both the hot and cold side the thermo-electric effects at the may augment the thermo-electric effects of the external junctions. In order to maximize this effect in general the material of the intermediate connector must have as high a thermal conductivity kₜ and electrical conductivity kₑ as possible and its Seebeck coefficient α should be as close as possible to that of the pellet to which it is connected. As said herein above, the thermo-electric effects at the external junctions can be optimized by selecting different thermo-electric materials for the pellets at the hot and cold side. In such a case it is not possible to match the Seebeck coefficient of a single intermediate connector to both the hot and cold side pellets. The solution to this is to provide an intermediate connector comprised of two or more segments of wire, wherein each segment is comprised of material having high kₜ and kₑ and having a different Seebeck coefficient. In this way an intermediate connector that is optimally matched to the pellet at both the hot and cold sides can be provided. Of course thermo-electric and resistance effects will occur at each junction between segments; however, by proper choice of material, these effects can be made essentially negligible and even to contribute to the overall heat transfer in the device.

Another way to optimally match the pellet at both the hot and cold sides and to maximize heat transfer across the split thermo-electric device is to create multi-stage splits, i.e. a thermo-electric chain, comprising a p,n-type pellet on the hot side, another p,n-type pellet on the cold side, and one or more p,n-type pellets in between with each pair of pellets in the chain connected by an intermediate connector. Examples of such structures comprised of two pellets and one intermediate connector, three pellets and two intermediate connectors, and three pellets and two intermediate connectors are schematically shown in FIGS. 4A, 4B, and 4C respectively. In these figures the pellets and intermediate connectors are identified by numerals 1, 2, . . . from the cold side of the chain to the hot side. A1 and L1 represent the cross-sectional area and length of pellet 1, A2 and L2 the same parameters of intermediate connector 2, etc. T1 is the temperature at the interface of pellet 1 with the intermediate substrate on the hot side, T2 is the temperature at the interface of pellet 1 with intermediate connector 2, T3 is the temperature at the interface of intermediate connector 2 with pellet 3, etc.

Referring to FIG. 4A, it can be shown that the heat flux q₁ across the interface where T=T1=T₁ and the heat flux q₂ across the interface where T=T2=T₂ can be determined from the following equations:

$$\begin{matrix}{q}_{1} = I α {T}_{1} - \frac{{I}^{2} {r}_{e} {η}_{1}}{2} - \frac{{k}_{t}}{{η}_{1}} ( {T}_{2} - {T}_{1} ) & equation 4 ( a ) \\ {q}_{2} = I α {T}_{2} - \frac{{I}^{2} {r}_{e} {η}_{1}}{2} - \frac{{k}_{t}}{{η}_{1}} ( {T}_{2} - {T}_{1} ) & equation 4 ( b )\end{matrix}$$

Wherein: α, rₑ, kₜ, are the Seebeck coefficient, electrical resistivity, and thermal conductivity and η₁=L1/A1; all for the first thermo-electric element.

Analogous equations can be written for each of the other elements, i.e. pellets and intermediate connectors, in the chain and these equations can be solved to determine parameters of the device, e.g. the internal temperatures at the various interfaces, or to determine the properties and/or dimensions of the materials that should be used when designing a thermo-electric device for use in a specific application.

To demonstrate this examples of how changes in the internal dimensions of the elements in the chain affect the internal temperature gradient for various structures and given boundary conditions will now be given. For simplicity in all the examples the thermo-electric pellets are all made from Bi2Te3 having α=200 microV/K, rₑ=10 micro ohm m, and kₜ=1.4 W/Km and all intermediate connectors are all made from copper having α=6 microV/K, rₑ=17 n ohm m, and kₜ=400 W/Km. All dimensions are in millimeters and all temperatures are in degrees Celsius.

### Example 1

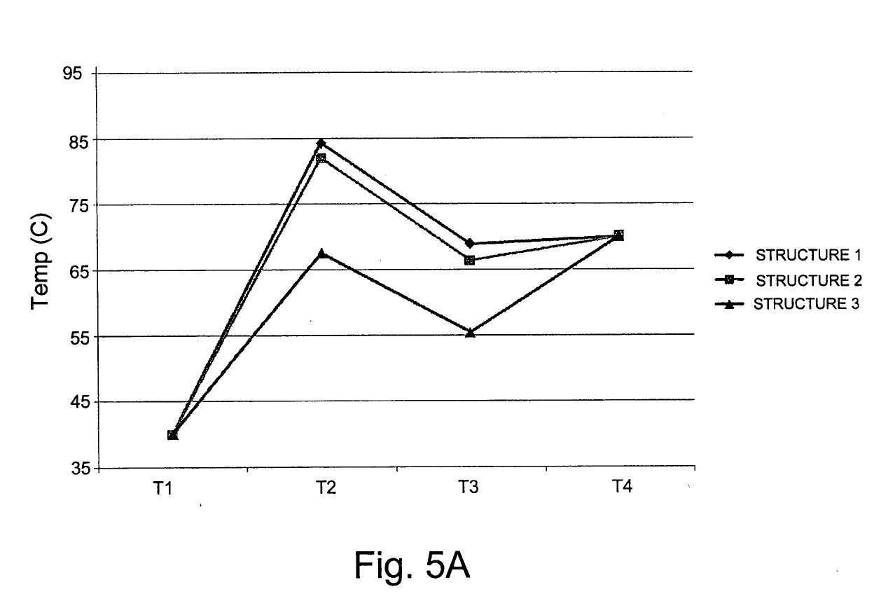

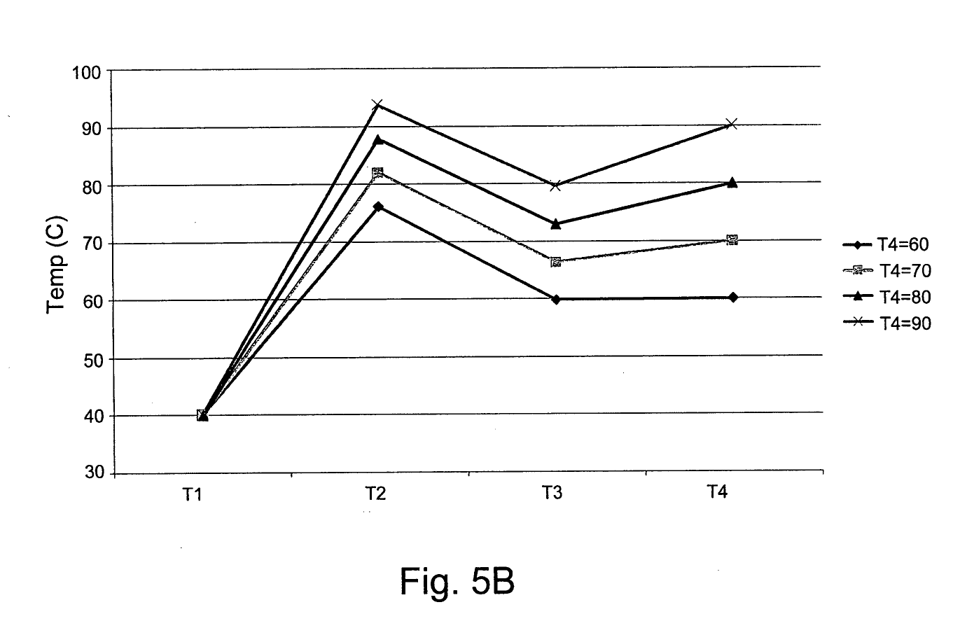

Three split thermo-electric structures similar to that shown in FIG. 4A are constructed wherein L1=L3=1 mm and L2=40 mm for all three structures. The boundary conditions are T1=40 degC and T4=70 degC for all structures. The cross-sectional areas of the elements and internal interface temperatures are as shown in Table 1. The temperatures at the interfaces between elements of the thermo-electric structures of this example are shown in FIG. 5A.

TABLE 1

| Structure | A1 | A2 | A3 | T1 | T2 | T3 | T4 |
|---|---|---|---|---|---|---|---|
| 1 | 9 | 7 | 9 | 40 | 84 | 69 | 70 |
| 2 | 9 | 7 | 16 | 40 | 82 | 66 | 70 |
| 3 | 16 | 7 | 9 | 40 | 68 | 55 | 70 |

### Example 2

Four split thermo-electric structures similar to that shown in FIG. 4A are constructed wherein L1=L3=1 mm and L2=40 mm for all four structures. A1=9 mm², A2=7 mm², and A3=16 mm² for all four structures. The boundary conditions are T1=40 degC and T4=60, 70, 80, and 90 degC for each of the structures respectively. The temperatures at the interfaces between elements of the thermo-electric structures of this example are shown in Table 2 and FIG. 5B.

TABLE 2

| Structure | T1 | T2 | T3 | T4 |
|---|---|---|---|---|
| 1 | 40 | 76 | 60 | 60 |
| 2 | 40 | 82 | 66 | 70 |
| 3 | 40 | 88 | 73 | 80 |
| 4 | 40 | 94 | 80 | 90 |

### Example 3

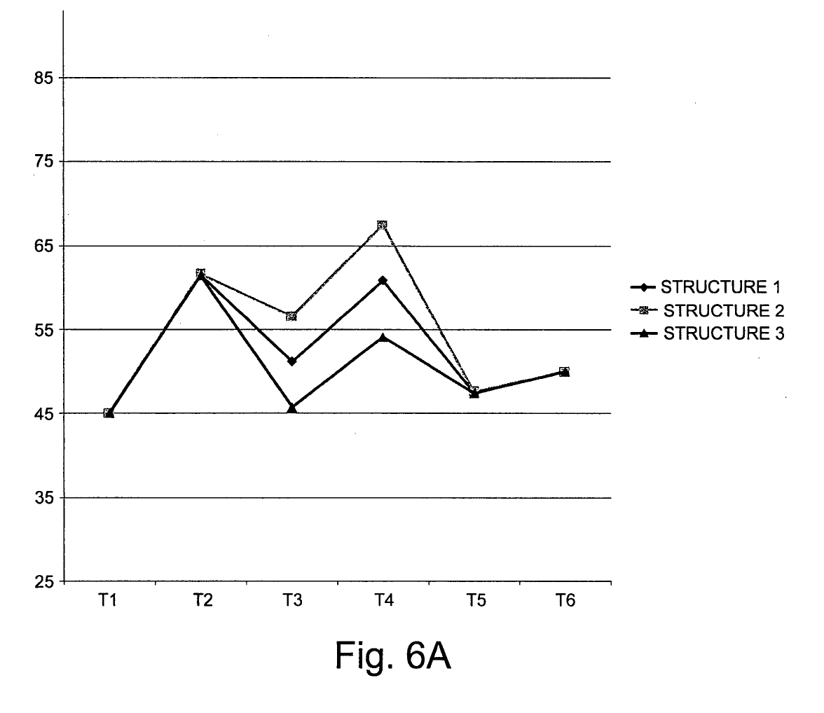

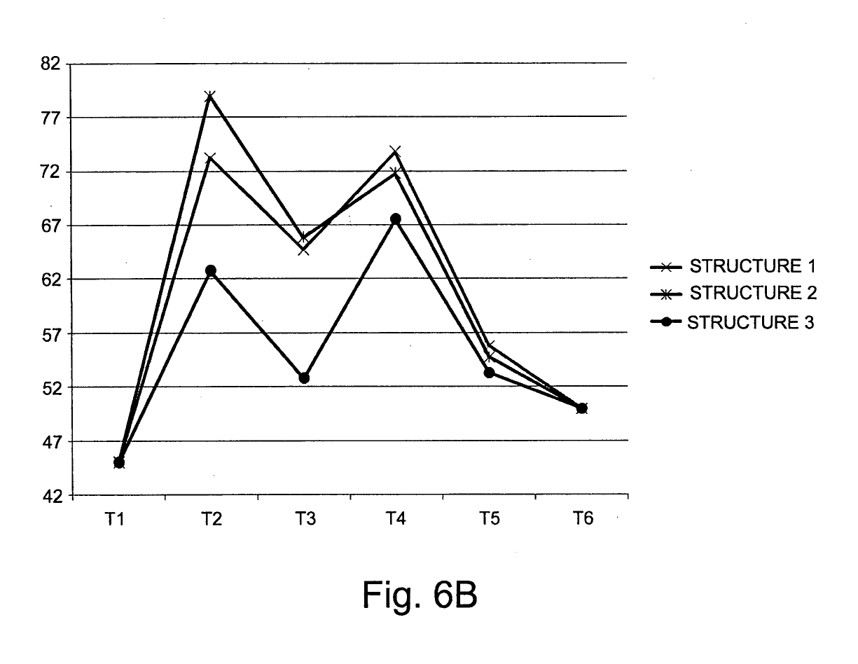

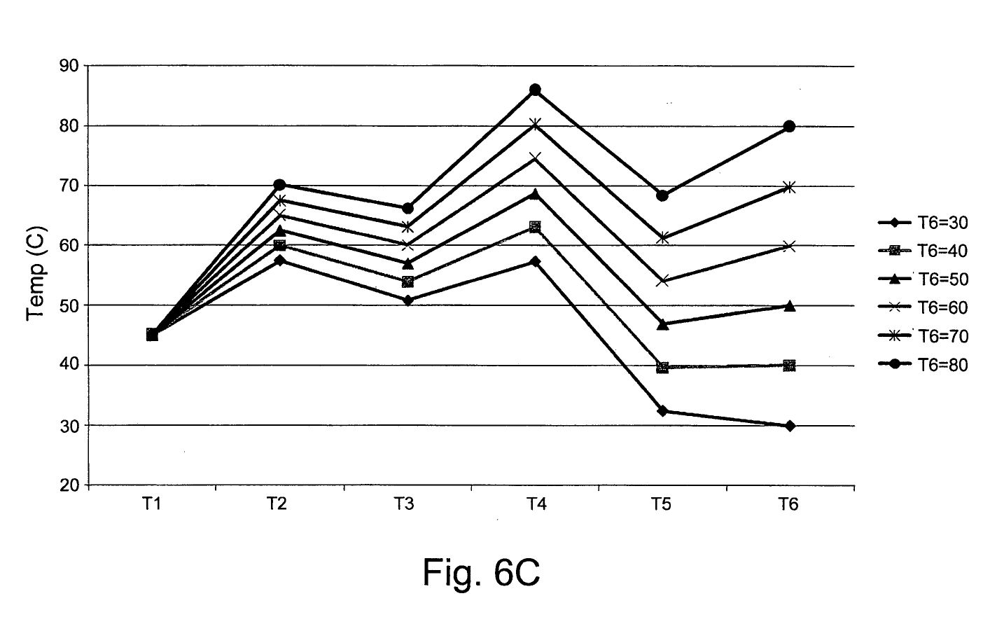

Three split thermo-electric structures similar to that shown in FIG. 4B are constructed wherein A1=25 mm2, A2=7 mm², A3=25 mm², A4=7 mm², and A5=25 mm² for all three structures. The boundary conditions are T1=45 degC and T6=50 degC for all structures. The lengths of the elements and internal interface temperatures are as shown in Table 3. The temperatures at the interfaces between elements of the thermo-electric structures of this example are shown in FIG. 6A.

TABLE 3

| Structure | L1 | L2 | L3 | L4 | L5 | T1 | T2 | T3 | T4 | T5 | T6 |
|---|---|---|---|---|---|---|---|---|---|---|---|
| 1 | 1 | 40 | 1 | 40 | 1 | 45 | 62 | 51 | 61 | 47 | 50 |
| 2 | 1 | 20 | 1 | 60 | 1 | 45 | 62 | 57 | 67 | 48 | 50 |
| 3 | 1 | 60 | 1 | 20 | 1 | 45 | 61 | 46 | 54 | 47 | 50 |

### Example 4

Three split thermo-electric structures similar to that shown in FIG. 4B are constructed The boundary conditions are the same as in Example 3, i.e. T1=45 degC and T6=50 degC for all structures. The lengths and cross-sectional areas of the elements and the internal interface temperatures are as shown in Table 4. The temperatures at the interfaces between elements of the thermo-electric structures of this example are shown in FIG. 6B.

TABLE 4

| Structure | L1 | L2 | L3 | L4 | L5 | A1 | A2 | A3 | A4 | A5 | T1 | T2 | T3 | T4 | T5 | T6 |
|---|---|---|---|---|---|---|---|---|---|---|---|---|---|---|---|---|
| 1 | 1 | 30 | 1 | 50 | 1 | 15 | 7 | 25 | 7 | 10 | 45 | 73 | 65 | 74 | 56 | 50 |
| 2 | 1 | 40 | 1 | 40 | 1 | 11 | 7 | 16 | 7 | 25 | 45 | 79 | 66 | 72 | 55 | 50 |
| 3 | 1 | 40 | 1 | 40 | 1 | 25 | 7 | 16 | 7 | 11 | 45 | 63 | 53 | 68 | 53 | 50 |

### Example 5

Six split thermo-electric structures similar to that shown in FIG. 4B are constructed wherein L1=L3=L5=1 mm, L2=20 mm, and L4=60 mm for all six structures. A1=A3=A5=25 mm² and A2=A4=7 mm². The boundary conditions are T1=40 degC degrees and T6=30, 40, 50, 60, 70, and 80 degC for each of the structures respectively. The temperatures at the interfaces between elements of the thermo-electric structures of this example are shown in Table 5 and FIG. 6C.

TABLE 5

| Structure | T1 | T2 | T3 | T4 | T5 | T6 |
|---|---|---|---|---|---|---|
| 1 | 45 | 57 | 51 | 57 | 32 | 30 |
| 2 | 45 | 60 | 54 | 63 | 40 | 40 |
| 3 | 45 | 63 | 57 | 69 | 47 | 50 |
| 4 | 45 | 65 | 60 | 75 | 54 | 60 |
| 5 | 45 | 68 | 63 | 80 | 61 | 70 |
| 6 | 45 | 70 | 66 | 86 | 69 | 80 |

### Example 6

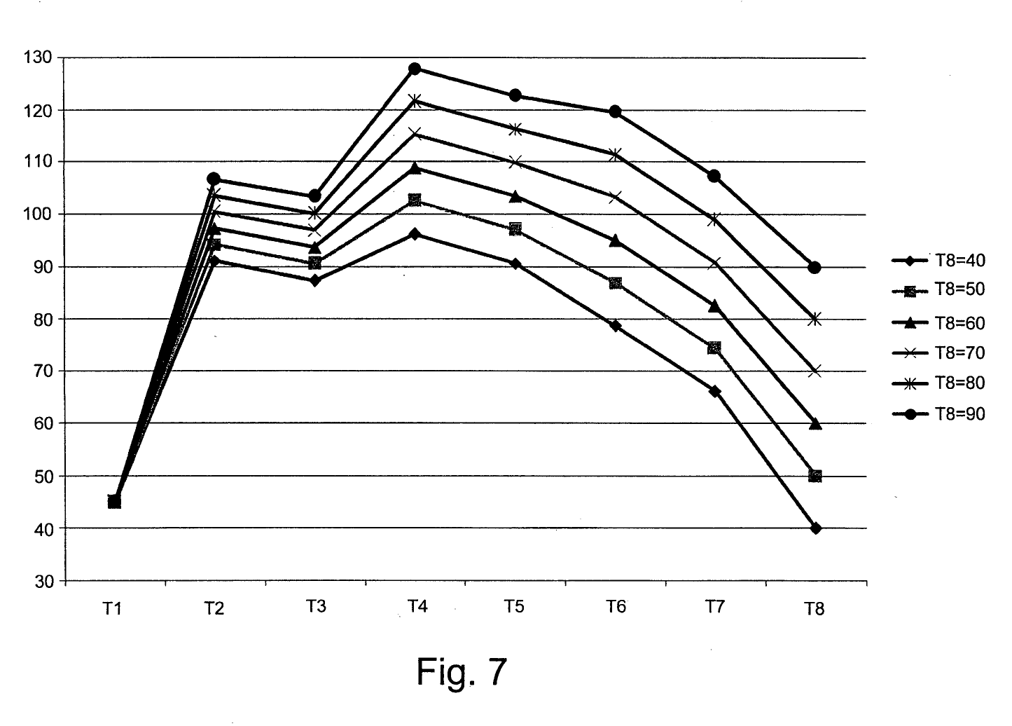

Six split thermo-electric structures similar to that shown in FIG. 4C are constructed wherein L1=L3=L5=L7=1 mm, L2=L4=10 mm, and L6=20 mm for all six structures. A1=A3=A5=25 mm² and A2=A4=7 mm². The boundary conditions are T1=45 degC and T8=40, 50, 60, 70, 80, and 90 degC for each of the structures respectively. The temperatures at the interfaces between elements of the thermo-electric structures of this example are shown in Table 6 and FIG. 7.

TABLE 6

| Structure | T1 | T2 | T3 | T4 | T5 | T6 | T7 | T8 |
|---|---|---|---|---|---|---|---|---|
| 1 | 45 | 91 | 87 | 96 | 91 | 79 | 66 | 40 |
| 2 | 45 | 94 | 91 | 103 | 97 | 87 | 74 | 50 |
| 3 | 45 | 97 | 94 | 109 | 103 | 95 | 83 | 60 |
| 4 | 45 | 100 | 97 | 115 | 110 | 103 | 91 | 70 |
| 5 | 45 | 104 | 100 | 122 | 116 | 111 | 99 | 80 |
| 6 | 45 | 107 | 103 | 128 | 123 | 120 | 107 | 90 |

To sum up, it is believed by the inventor that the over-standardization of the existing thermo-electric modules has left the designer of thermo-electric systems based on these modules very few degrees of freedom at best and none at all at worst. This being the case, the typical standard module requires the designer to design the application around the module instead of the other way around. The present invention was conceived to eliminate most of the limitations of the prior art devices on the one hand, while on the other hand, to introduce more possibilities for improving and controlling the performance of the thermo-electric effect and efficiency. Thus the present invention allows the designer to focus on providing a suitable thermo-electric device for a given application and system. Moreover, for a given application the split concept allows optimization of the overall performance based on the ability to change the parameters of all of the elements of the module.

The rising demand for utilization of renewable energy sources and in parallel the growing awareness of environmental aspects have encouraged a variety of innovative approaches from many areas of science and technology. Advancement directed towards a new generation of thermo-electric structures or systems is one of the promising challenges in the development of energy alternatives, which can have a significant economic and environmental impact. The present invention as described herein above is not intended or anticipated to be related in any way only to the particular applications or systems described herein but in fact the principles of the invention can be applied to any thermo-electric application or system for cooling, heating, or for power generation.

Moreover, the inventor believes that the specific technical details, e.g. the method of soldering or clamping the pellets to the intermediate connections, the method of attaching the pellets to the support layers, the composition of the intermediate connectors, and the composition of the p,n pellets and their dimensions, are to be chosen individually according to the requirements of the particular system under consideration. With this in mind, a wide spectrum of applications will now be described in terms of categories of applications, rather than specific applications.

### 1. Currently Known Applications:

At present, companies worldwide extensively utilize the standard thermo-electric modules for cooling (or energy generation) in various fields of technology such as: electronics, temperature control and temperature stabilization, modern space systems, tele-communications, electronic devices, optical and medical power systems, and many other scientific and laboratory systems. Another sub-category of existing applications is the use of the standard thermo-electric modules for industrial cooling, e.g. refrigerators, air-conditioning or water coolers in ships, cars, and railway carriages. All the above are only examples of existing applications which would benefit by adopting the structure and method of the present invention as conceptually described herein. The present invention when applied to the current applications would reduce the complexity, simplify the design and upgrade the overall performance of devices for cooling or power generation.

### 2. Stand-Alone Alternative Electro Energy Systems

Another most interesting direction of applications is in developing electro-energy in micro self-energy systems. Interest in micro-energy systems is increasing as part of the worldwide search for alternative (renewable) energy sources. Achievements and developments in the field of thermo-electric technology and thermo-electric modules may become a vital and valid choice for such applications. A few examples of these applications are: small-scale stand-alone power and cooling systems; portable electric generators capable of producing a few hundreds of watts of electricity for use by army units in the field; units for power generation for light, air conditioning, or general electricity supply for remote areas where an electric infrastructure does not exist; and thermo-electric batteries-chargers. In all of the above examples and others, the heat source may be directly from solar radiation or from a working thermal fluid such as oil-heated by solar energy, fuel, or exhaust gases from motors. In parallel the heat sink can be the ambient environment, the wind, or an available coolant such as a river or body of water.

It is noted that solar cells or panels are well-known as producers of a heat source (or high temperature gradient). However, when low heat flux is involved, natural convection heat sinks may yield only lower power; however, available remote liquid cooled heat sinks for instance, may provide very high thermal performance.

### 3. Large-Scale Systems

Last but not least, large scale application challenges are not being met using the currently available thermo-electric technology. Whereas the standard thermo-electric modules can only be used with small, sometimes miniature systems; the herein described split structure opens a large range of technology for meeting the challenges and the needs of large scale systems. For example, energy lost from extremely hot engines or exhaust pipes in vehicles can be utilized if the heat absorber is attached directly to the engine block or exhaust and the heat sink is located at the front of the moving vehicle where heat sinking (heat dissipation) is by forced convection and hence can be capable of absorbing a large heat flux without exhibiting any increase in temperature. In this and similar systems the heat sink is an integral part of the thermo-electric system and may determine the total system performance. Stated differently the thermo-electric unit of the invention can be used to turn waste heat from moving vehicles or hot gases released from power stations, etc. and the existing radiator or ambient temperature into a thermo-electric energy recovery device.

As stated earlier, one of the principal goals of the present invention is to provide a new technology for thermo-electric units based on split structure, wherein the heat transport mechanisms at the hot and/or cold sides are separate and disengaged from each other. This can be applied for cooling or heating thermo-electric modules, as well as for power generation modules, which in turn can be applied to any existing applications where thermo-electric units are utilized. Additionally, the thermo-electric units of the invention can be applied to a wide range of large-scale applications.

Specific examples of embodiments and inventions and uses thereof have been provided for the purpose of illustration only and these examples are not intended to limit invention in any way. The scope of the invention is not intended by the inventors to be limited in any way by the drawings, arrangements or parameters described. Moreover, it is anticipated that new developments which may come in the fields of advanced new, thermo-electric materials, thin film materials, high temperature thermo-electric materials for high temperature gradients, etc. can be adopted and assimilated accordingly in the general concept of the thermo-electric structure of the invention as presented herein.

Although embodiments of the invention have been described by way of illustration, it will be understood that the invention may be carried out with many variations, modifications, and adaptations, without exceeding the scope of the claims.

1-15. (canceled)

16. A Split-Thermo-Electric Structure (STES) comprising:
a) a first thermo-electric element at a high temperature; and
b) a second thermo-electric element at a low temperature; wherein, said first and said second thermo-electric elements are connected electrically and thermally in series in one of the following ways:
i) by means of an intermediate connector made of one segment of material or by two or more segments of different materials joined together, wherein the materials of which said intermediate connector is made have high electrical and thermal conductivities relative to the electrical and thermal conductivities of the thermo-electric elements to which said intermediate connector is connected; and
ii) by means of a chain comprised of said first and second thermo-electric elements and one or more additional thermo-electric elements located between them,
wherein: each consecutive thermo-electric element in said chain is electrically and thermally connected to the thermo-electric elements adjacent to it by an intermediate connector made of a piece of material or by two or more pieces of different materials joined together, wherein the materials of which each of said intermediate connectors are made have high electrical and thermal conductivities relative to the electrical and thermal conductivities of the thermo-electric elements to which said intermediate connector are connected;
wherein, at least one of the material and the dimensions of which said first thermo-electric element is made is different from the material and the dimensions of which said second thermo-electric element is made.

17. The STES of claim 16, wherein the thermo-electric elements are each made of one of the following types of material: a metal, a p-type semi-conductor material, an n-type semi-conductor material or an i-type semi-conductor material.

18. The STES of claim 16, which is a Seebeck device, wherein the connections between the first and the second elements are maintained at different temperatures such at to generate an electrical current along the connections that connect them.

19. The STES of claim 16, which is a Peltier device, wherein a current is caused to flow through the connections that connect the first and the second elements, thereby to cool said first element and heat said second element.

20. A system utilizing one or more STESs according to claim 18, wherein the source of high temperature is from waste heat.

21. A system according to claim 20, wherein the waste heat is generated by a vehicle.

22. A system utilizing one or more STESs according to claim 18, wherein the source of the high temperature is the sun.

23. A system utilizing one or more STESs according to claim 21, wherein the second element is cooled by the cooling system of a moving vehicle.

24. A thermo-electric device comprising a plurality of pairs of STESs according to claim 16, wherein one STES in each pair is comprised of p-type semiconductor elements and the other STES in said pair is comprised of n-type semiconductor elements, wherein the first thermo-electric element of each STES in said device is attached to a first support layer and the second thermo-electric element of each STES in said device is attached to a second support layer, wherein said first and said second support layers comprise metallic conductor tabs on their surface that electrically connect all STESs in said device in series.

25. A system utilizing the thermo-electric device of claim 24, wherein the first support layer is thermally connected to a heat source and the second support layer is thermally connected to a heat sink.

26. The system of claim 25, which is a Seebeck device, wherein the first support layer and the second support layer are maintained at different temperatures thereby generating an electrical current along the STESs that connect them.

27. The system of claim 25, which is a Peltier device, wherein a current is caused to flow through the STESs that connect the first support layer and the second support layer, thereby cooling said first support layer and heating said second support layer.

28. The system of claim 25 wherein either the heat source or the heat sink or both are located at a distance from their respective support layer.
